(19) United States
(12) Patent Application Publication
(10) Pub. No.: US 2011/0206833 A1
(43) Pub. Date: Aug. 25, 2011

(54) EXTENSION ELECTRODE OF PLASMA BEVEL ETCHING APPARATUS AND METHOD OF MANUFACTURE THEREOF

(75) Inventors: Gregory Sexton, Fremont, CA (US); Paul Aponte, San Jose, CA (US)

(73) Assignee: Lam Research Corporation, Fremont, CA (US)

(21) Appl. No.: 13/025,504

(22) Filed: Feb. 11, 2011

Related U.S. Application Data
(60) Provisional application No. 61/306,676, filed on Feb. 22, 2010.

(51) Int. Cl. B05D 5/12; H01L 21/306; B08B 7/00

(52) U.S. Cl. 427/78; 156/345.43; 156/345.3; 134/1.1

(57) ABSTRACT

An extension electrode with enhanced durability and etching rate for plasma bevel etchers. The extension electrode comprises a plasma exposed truncated conical surface on an annular aluminum body. The aluminum body can roughened prior to anodization and coated with a ceramic material such as yttria.

This application claims priority under 35 U.S.C. §119(e) to U.S. Provisional Application No. 61/306,676 entitled EXTENSION ELECTRODE OF PLASMA BEVEL ETCHING APPARATUS AND METHOD OF MANUFACTURE THEREOF, filed Feb. 22, 2010, the entire content of which is hereby incorporated by reference.

### BACKGROUND

In processing a semiconductor substrate, plasma is often employed to etch intended device features in the substrate or films deposited thereon. Typically, plasma density is lower near the edge of the substrate, which may lead to accumulation of a byproduct layer (such as poly-silicon, nitride, metal, etc.) on the top and bottom surfaces of the substrate bevel edge. The byproduct layer may peel or flake off, often onto critical areas of the substrate during transport and succeeding processing steps, thereby leading to lower yield of devices from the substrate. Therefore, it is highly desirable to remove the byproduct from the substrate bevel edge before the substrate goes through the next processing step. One highly effective process is to use plasma to etch away the deposited byproduct on the bevel edge. This process is named plasma bevel etching. An apparatus to carry out this process is a plasma bevel etcher. In a plasma bevel etcher, electrodes around the substrate bevel edge (extension electrodes) are periodically cleaned to remove byproduct deposition on them. Such cleaning can lead to excessive wear and high cost of consumables due to need to replace the extension electrodes.

### SUMMARY

In accordance with a preferred embodiment, an extension electrode in a plasma bevel etcher is provided with improved service life by designing the plasma-exposed surface to have an inwardly facing, truncated conical surface, without any recesses or steps.

In accordance with a preferred embodiment, the plasma-exposed surface of an extension electrode is roughened before anodization and coated with plasma sprayed yttria.

### BRIEF DESCRIPTION OF DRAWINGS

FIG. 1 shows a schematic cross sectional diagram of an exemplary plasma bevel etcher. For simplicity, only half of the cross section is shown.

FIG. 2 shows an enlarged schematic diagram of region A in FIG. 1.

FIG. 3 shows a schematic of an improved design of the region A in FIG. 1, in accordance with an embodiment.

FIG. 4 shows an overlay of an extension electrode in a prior art plasma bevel etcher, and the extension electrode in an embodiment.

FIG. 5 shows a bottom view of the extension electrode in an embodiment.

FIG. 6 shows a cross sectional view along a diameter of the extension electrode in an embodiment.

FIG. 7 shows an enlarged view of region C in FIG. 6.

FIG. 8 shows a top view of the extension electrode in an embodiment.

FIG. 9 shows an enlarged view of region D in FIG. 8.

### DETAILED DESCRIPTION

In a plasma etching process of a semiconductor substrate, free radicals in the plasma chemically react with the substrate and/or films deposited thereon. The reaction product is unwanted on the finished substrate and should be transported away into the exhaust. However, as the unwanted product (byproduct) exits the plasma, it tends to redeposit on exposed surfaces such as the bevel edge of the substrate. The byproduct deposition must be removed before it becomes excessive, or it will delaminate and land on critical areas on the substrate and lower the device yield. The byproduct deposition can also cause a reduction in the efficiency of the plasma etching process (i.e. lower etch rate).

In a plasma bevel etcher, extension electrodes are the electrodes arranged along the bevel edge of the substrate. A plasma bevel etcher is described in commonly assigned US Patent Application Publication No. 2008/0227301, which is hereby incorporated by reference. The extension electrodes can be anodized aluminum with yttria coating. Yttria coating for plasma applications is described in commonly assigned U.S. Pat. Nos. 7,311,797, 7,300,537 and 7,220,497, which are hereby incorporated by reference. Due to the location of the extension electrodes, they often receive heavy byproduct deposition and must be cleaned periodically. Removing the byproduct deposition is not an easy task. Adherent chemical species such as aluminum fluoride and polymers are common in such byproduct. Effective cleaning often involves rigorous abrasion, which can lead to damage to the yttria coating and high consumable cost. To facilitate the cleaning process, it is highly desirable to increase the adhesion strength of the yttria coating and make the geometrical shape of the plasma-exposed surface of the extension electrodes simple, specifically, without corners, steps and the like.

A new and improved extension electrode with enhanced adhesion to a plasma exposed yttria coating and simplified geometry is described herein.

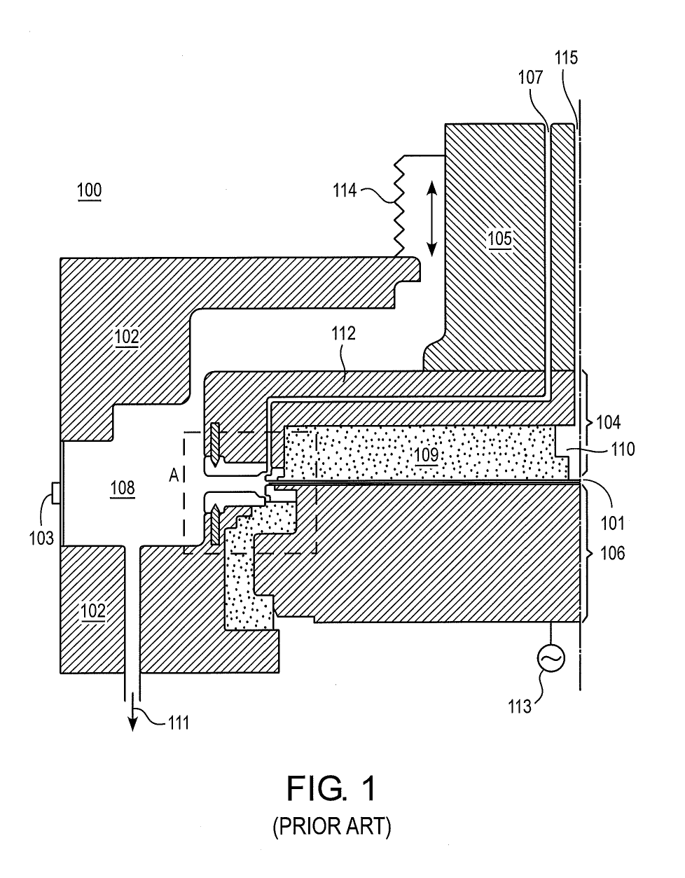

FIG. 1 is a schematic cross sectional diagram of a prior art bevel etcher 100 for cleaning the bevel edge of a substrate 101. The bevel etcher 100 has a generally, but not limited to, axisymmetric shape and, for brevity, only half of the side cross sectional view is shown in FIG. 1. As depicted, the bevel etcher 100 includes: a chamber wall 102 having a loading gate 103 through which the substrate 101 is loaded and unloaded; an upper electrode assembly 104; a support 105 from which the upper electrode assembly 104 is suspended; and a lower electrode assembly 106. The support 105 moves the upper electrode assembly 104 up and down (in the direction of the double arrow) for loading/unloading the substrate 101. A precision driving mechanism (not shown in FIG. 1) is attached to the support 105 so that the gap between the upper electrode assembly 104 and the substrate 101 is controlled accurately.

Metal bellows 114 are used to form a vacuum seal between the chamber wall 102 and support 105 while allowing the support 105 to have a vertical motion relative to the wall 102. The support 105 has a center gas feed 115 and an edge gas feed 107. The gas feeds 115 and 107 provide gases used in bevel edge etching. The center gas feed 115 can be used to flow a purge gas such as nitrogen over the substrate 101 and the edge gas feed 107 can be used to supply a plasma etching gas to a reaction zone in the vicinity of the bevel edge of the substrate. During operation, plasma is formed around the bevel edge of the substrate 101 and has a generally ring shape. To prevent the plasma from reaching the central portion of the substrate 101 and affect the device die area, the space between an insulator plate 109 in the upper electrode assembly 104 and the substrate 101 is small and a gas is fed from the center gas feed 115, preferably through a stepped hole 110. Then, the gas passes through the gap between the upper electrode assembly 104 and the substrate 101 in the radial direction of the substrate. The exhaust gases are withdrawn from the chamber space 108. During a bevel etching operation, the chamber pressure is typically maintained in the range of 500 mTorr to 2 Torr by a vacuum pump 111.

The upper electrode assembly 104 includes: an upper dielectric plate 109; and an upper metal component 112 secured to the support 105 by a suitable fastening mechanism and grounded via the support 105. The upper metal component 112 is preferably formed of a metal, such as aluminum, and may be anodized. The gas feeds 107 and 115 are routed through the upper metal component 112. The upper dielectric plate 109 is attached to the upper metal component 112 and formed of a dielectric material, preferably but not limited to ceramic (e.g. alumina). If desired, the upper dielectric plate 109 may have a coating of yttria. While the upper dielectric plate 109 is shown with a single center hole 110, the upper dielectric plate 109 may have any suitable number of outlets, e.g., the outlets can be arranged in a showerhead hole pattern if desired.

The lower electrode 106 is operable as a vacuum or electrostatic chuck to hold the substrate 101 in place during a bevel etching operation (details of the chuck not shown). The lower electrode 106 is coupled to a radio frequency (RF) power source 113 to receive RF power. During operation, the RF power source 113 provides RF power to energize a gas provided through at least one of the gas feeds 115 and 107 into plasma, wherein the RF power is preferably supplied at one or more frequencies in a range, but not limited to, of approximately 2 MHz to approximately 60 MHz.

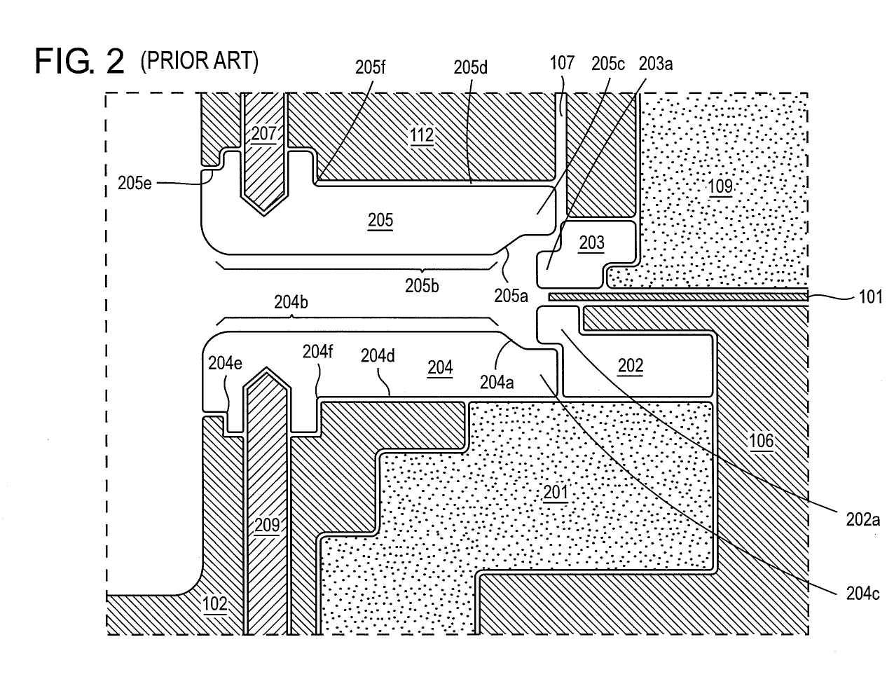

FIG. 2 shows an enlarged schematic diagram of region A in FIG. 1. The bottom dielectric ring 201 is formed of a dielectric material, such as ceramic (e.g. alumina), and electrically separates the lower electrode 106 from the chamber wall 102. The substrate 101 is mounted on the lower electrode 106. The diameter of the substrate 101 is larger than the diameter of the upper surface of the lower electrode 106. The bevel edge is sandwiched between a lower plasma-exclusion-zone (PEZ) ring 202 and an upper PEZ ring 203, which surround the lower electrode 106 and the upper dielectric plate 109, respectively. The term PEZ refers to an area over the substrate 101 from which the plasma is excluded.

The upper PEZ ring 203 has a lower outer flange 203a. An upper annular electrode 205 (extension electrode) surrounds the upper PEZ ring 203, with the inner portion 205c of the upper extension electrode 205 disposed above the outer flange 203a of the upper PEZ ring 203. The upper PEZ ring 203 is separated from the upper extension electrode 205 by a gap to allow gas flow through the gas feed 107. The upper extension electrode 205 has a step 205a on the plasma-exposed lower surface. The step 205a forms a thickened outer portion 205b, configured to decrease the overall distance of the upper extension electrode 205 to the substrate bevel edge and thus increase the bevel edge etching rate. The upper extension electrode 205 is fastened to the upper metal component 112 by a plurality of bolts 207, which are engaged in holes in an upper surface 205d of the upper extension electrode 205. The upper surface (mounting surface) 205d of the upper extension electrode 205 in contact with the upper metal component 112, comprises an inner step 205f and an outer step 205e. The outer step 205e and inner step 205f mate with an outer step and an inner step in the upper metal component 112, respectively.

The lower PEZ ring 202 has an upwardly extending outer flange 202a. A lower extension electrode 204 surrounds the lower PEZ ring 202, with the inner portion 204c of the lower extension electrode 204 disposed under the flange 202a of the lower PEZ ring 202. The lower extension electrode 204 has a step 204a on the plasma-exposed upper surface. The step 204a forms a thickened outer portion 204b. The lower extension electrode 204 is fastened to the chamber wall 102 by a plurality of bolts 209, which are engaged in holes in a lower surface 204d of the lower extension electrode 204. The lower surface (mounting surface) 204d of the lower extension electrode 204 in contact with the chamber wall 102, comprises an inner step 204f and an outer step 204e. The outer step 204e and inner step 204f mate with an outer step and an inner step in the chamber wall 102, respectively.

The extension electrodes 204 and 205 in FIG. 2 are preferably machined rings of aluminum. The aluminum is preferably a semiconductor processing compatible alloy. To extend service life and minimize contamination, the extension electrodes 204 and 205 are anodized and coated with yttria.

The plasma-exposed surfaces of the extension electrodes 204 and 205 typically receive heavy byproduct deposition. As a result, the extension electrodes 204 and 205 require periodic abrasive cleaning or replacement when the byproduct deposition becomes excessive. Due to the high cost of manufacturing the yttria-coated extension electrodes 204 and 205, it is desirable to clean and reuse them for economical reasons.

However, cleaning can lead to damage and wear of the yttria coating. In the extension electrodes 204 and 205, the steps 204a and 205a make cleaning more difficult and leads to even higher rate of damage with eventual loss of the yttria coating at the outer corners of the steps 204a and 205a.

The embodiments described herein provide improvement over the prior art upper extension electrode 205 as depicted in FIG. 2, in that the adhesion of the yttria coating is enhanced and the shape of the upper extension electrode is optimized to facilitate cleaning.

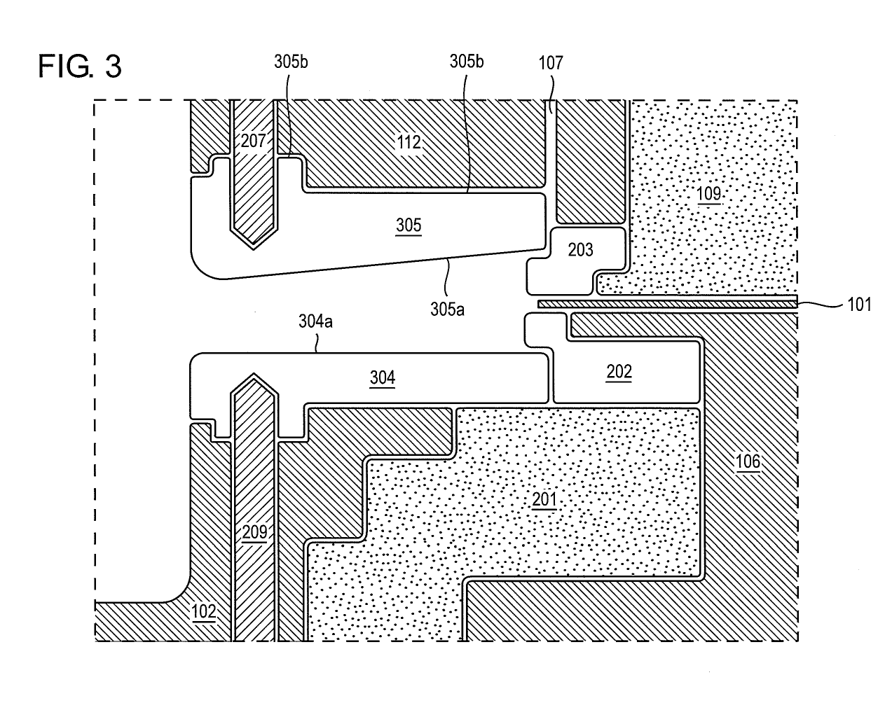

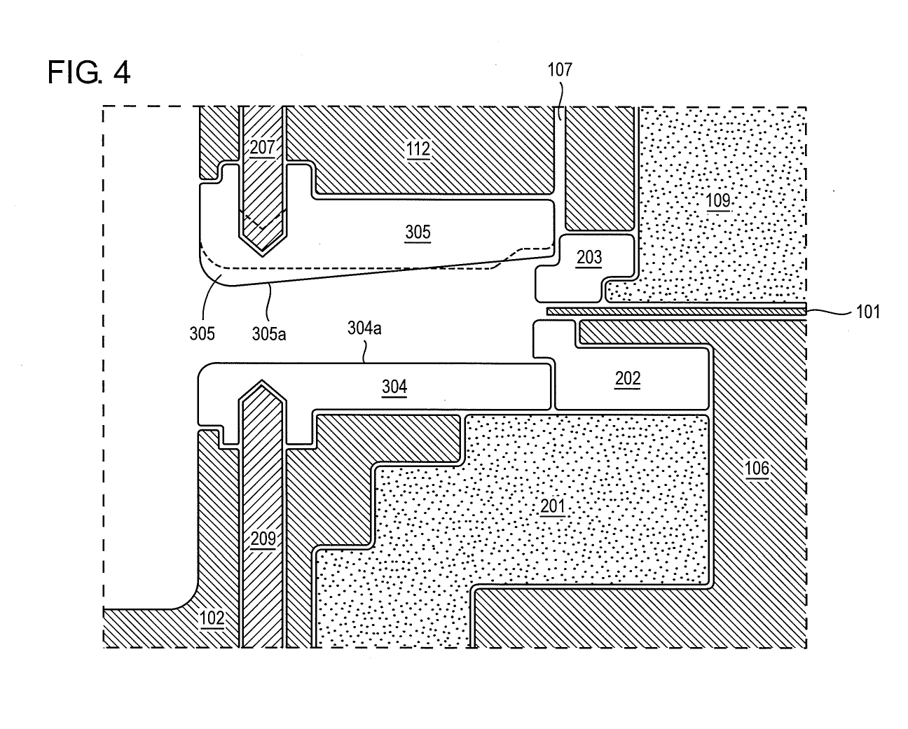

FIG. 3 shows a schematic cross sectional diagram of the proximity of the substrate bevel edge in a plasma bevel etcher chamber, according to one embodiment. The components depicted in FIG. 3 correspond to those in FIG. 2 except that the upper extension electrode 305 comprises a plasma-exposed surface 305a having a truncated cone shape and the lower extension electrode 304 comprises a plasma-exposed flat surface 304a. The surfaces 304a and 305a are continuous surfaces which do not have any steps or recesses. The upper extension electrode 305 and its counterpart 205 are superimposed in FIG. 4 wherein the upper extension electrode 205 is shown in dotted lines. The upper extension electrode 305 has an outer portion which is preferably about 2 mm (“about” as used herein means ±10%) thicker than the extension electrode 205 and a lower inner corner about 0.5 mm closer to the substrate 101 compared to the upper extension electrode 205, in order to maintain the same etching rate.

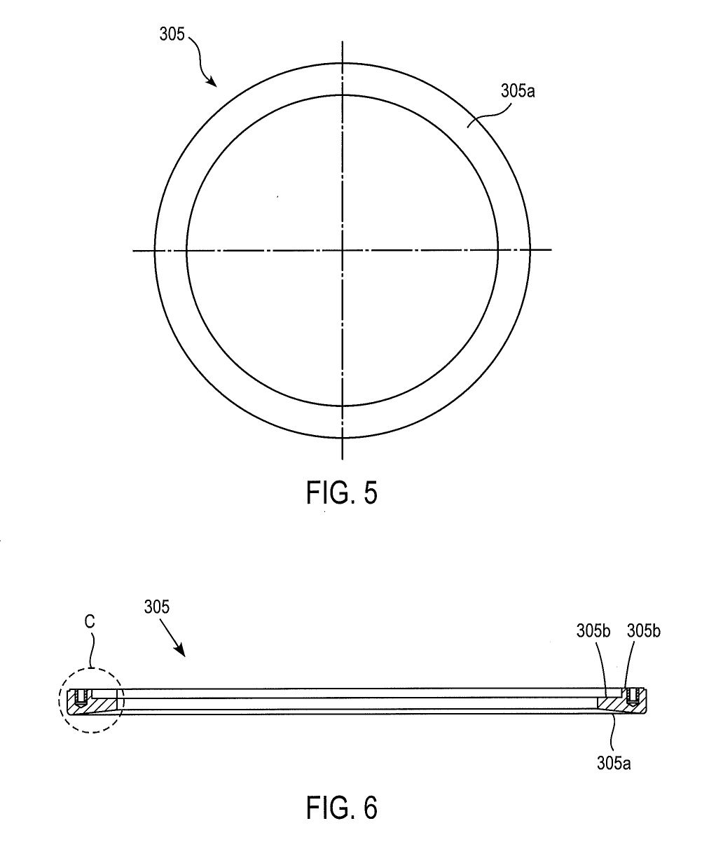

FIG. 5 shows a bottom view of the upper extension electrode 305. The outer diameter of the upper extension electrode 305 is preferably about 14.2 inches and the inner diameter is preferably about 11.8 inches. The plasma exposed surface 305a has a width of about 1.2 inches.

FIG. 6 shows a cross-sectional view of the upper extension electrode 305 along a diameter.

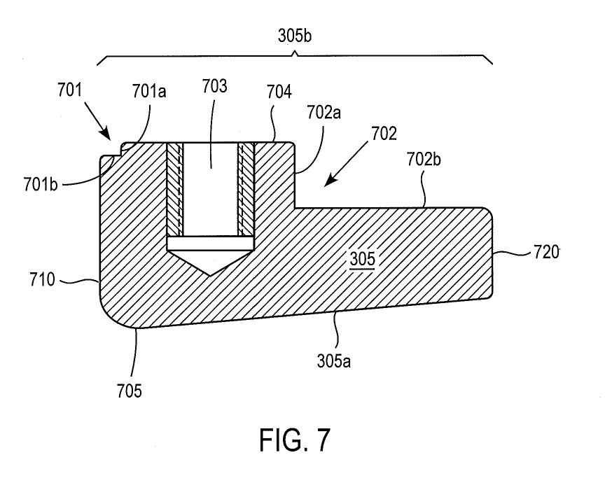

FIG. 7 shows an enlarged view of the area C of FIG. 6. The upper extension electrode 305 comprises an outer step 701, sixteen tapped mounting holes 703 and an inner step 702 on a mounting surface 305b. The outer step 701 preferably has an inner diameter of about 14.1 inches and an outer diameter of about 14.2 inches. The outer step 701 has a vertical surface 701a which preferably extends about 0.04 inch and a horizontal surface 701b which extends about 0.1 inch. The inner step 702 preferably has an inner diameter of about 11.8 inches and an outer diameter of 13.0 inches. The inner step 702 has a vertical surface 702a which preferably extends about 0.2 inch and a horizontal surface 702b which extends about 0.6 inch. The depth of the tapped mounting holes 703 is preferably about 0.4 inch. The mounting holes have diameters of about 0.1 to 0.4 inch.

The upper extension electrode 305 also comprises a lower truncated conical surface 305a. The outer thickness of the upper extension electrode 305, measured between the uppermost surface 704 and the lowest point 705 on the truncated conical surface 305a is preferably about 0.6 inch. The inner thickness, measured between the horizontal surface 702b of the inner step 702 at the corner of the inner periphery 720 and the truncated conical surface 305a, is preferably about 0.3 inch. All outward corners are preferably rounded with radii between 0.02 inch and 0.04 inch, except for the corner at 705 between the outer periphery 710 and the truncated conical surface 305a which is preferably rounded to a radius of about 0.1 inch. The angle between the tangent planes of the truncated conical surface 305a and the radial plane of the upper extension electrode 305 (or the horizontal surface 702b) can be up to 30°, preferably 2° to 8° (e.g. (2°, 3°, 4°, 5°, 6°, 7°, 8°), and more preferably 5°.

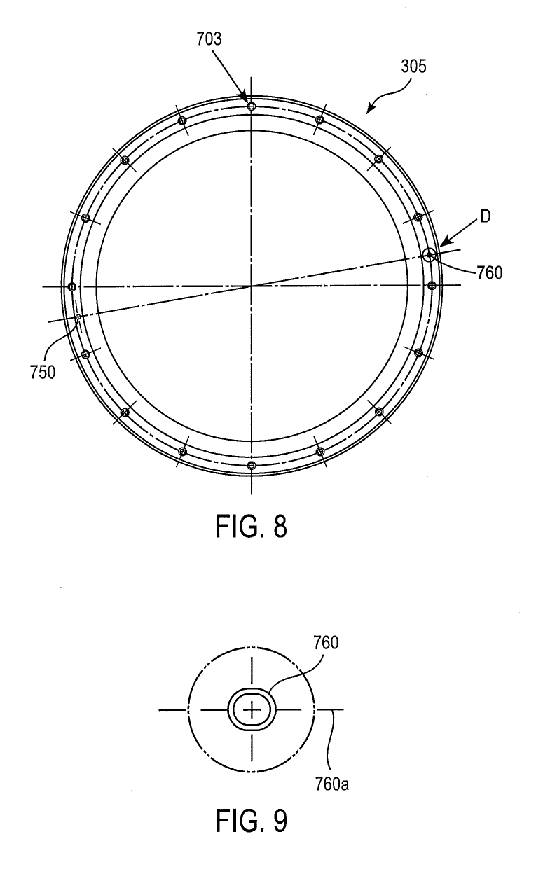

FIG. 8 shows a top view of the upper extension electrode 305. The sixteen tapped mounting holes 703 are preferably radially aligned at a radius of about 6.78 inches from the center axis of the upper extension electrode 305, offset by 22.5° between each pair of neighboring tapped mounting holes 703. The upper extension electrode 305 further comprises alignment pin holes on the mounting surface 305b such as a first alignment pin hole 750 and a second alignment pin hole 760, both holes for receipt of a respective alignment pin. The first alignment pin hole 750 is preferably located about 6.6 inches from the center axis of the electrode 305, offset from a tapped mounting hole 703 by 10° counterclockwise. The first alignment pin hole 750 preferably has a diameter of about 0.12 inch and a depth of about 0.24 inch. The entrance to the first alignment pin hole 750 has a 45° chamfer of about 0.02 inch wide. The first alignment pin hole 750 is a smooth (unthreaded) hole. FIG. 9 shows the details of the second alignment pin hole 760 in an enlarged view of the area D of FIG. 8. The second alignment pin hole 760 is preferably an elongated smooth (unthreaded) hole with its center preferably located about 6.78 inches from the center axis of the electrode 305, offset by 180° from the first alignment pin hole 750, and its longitudinal axis 760a in the radial direction of the extension electrode 305. The second alignment pin hole 760 preferably has a depth of about 0.24 inch, a width of about 0.119 inch perpendicular to its longitudinal axis 760a, a length of about 0.139 inch parallel to its longitudinal axis 760a. The entrance to the second alignment pin hole 760 preferably has a 45° chamfer of about 0.02 inch.

The extension electrodes 304 and 305 are preferably machined from a body of aluminum or aluminum alloy. To prevent extension electrode erosion and metal particle contamination to the substrate, the plasma-exposed surfaces, 305a and 304a, are anodized and coated with plasma-sprayed yttria. It is not necessary for the outer perimeter of the extension electrodes 304 and 305 to be coated with yttria because the outer perimeter is not directly exposed to the plasma and thus not under attack by the plasma. In order to enhance the adhesion of the yttria coating, at least the plasma-exposed surfaces, 305a and 304a are roughened (e.g. by bead blasting) before anodization to a roughness (Rₐ) of about 75 to 200 microinches, preferably to a roughness of about 160 to 200 microinches. The surfaces 305a and 304a are cleaned by any suitable cleaning process and anodized, preferably to a thickness of about 0.002 inch. The anodized surfaces 305a and 304a are then cleaned by any suitable cleaning process and plasma-spray-coated with yttria to provide a coating thickness of about 0.002 to 0.008 inch.

It should be appreciated that the extension electrodes may be configured to have any dimensions suitable for a particular hardware configuration. The roughened and recess-free plasma-exposed surfaces exhibit improved resistance to wear during periodic cleaning thereof.

We claim:

1. An upper extension electrode for a plasma bevel etcher used in semiconductor substrate processing wherein the plasma removes byproduct deposition from a bevel edge of a semiconductor substrate, the extension electrode comprising:
an annular body having an outer periphery, an inner periphery, a mounting surface and a plasma-exposed truncated conical surface extending from the outer periphery to the inner periphery, the extension electrode being operable to generate plasma during cleaning of the bevel edge of the semiconductor substrate in the bevel etcher.

2. The extension electrode of claim 1, wherein the outer periphery is thicker in an axial direction than the inner periphery.

3. The extension electrode of claim 2, wherein an angle between the tangent planes of the truncated conical surface and a radial plane of the extension electrode is between 2.5° and 7.5°.

4. The extension electrode of claim 1, wherein corners between the inner and outer peripheries and the truncated conical surface are rounded.

5. The extension electrode of claim 1, wherein the annular body is a machined ring of pure aluminum or an aluminum alloy.

6. The extension electrode of claim 1, further comprising a plurality of tapped holes in the mounting surface, the holes adapted to threadedly engage mounting bolts.

7. The extension electrode of claim 1, wherein the inner periphery has an inner diameter of at least 8 inches and the outer periphery has an outer diameter of 14.5 inches or less.

8. The extension electrode of claim 5, wherein the truncated conical surface is anodized.

9. The extension electrode of claim 5, wherein the truncated conical surface is coated with a ceramic coating material.

10. The extension electrode of claim 5, wherein the truncated conical surface comprises a plasma-sprayed coating on a roughened anodized surface having a roughness of 75 to 200 microinches.

11. The extension electrode of claim 9, wherein the ceramic coating material is a plasma-sprayed yttria coating having a thickness of about 0.002 to 0.008 inch.

12. A plasma bevel etcher for cleaning the bevel edge of a semiconductor substrate having a diameter of 8 inches or more, comprising the extension electrode of claim 1 as an upper extension electrode, disposed above an outer periphery of the semiconductor substrate.

13. The plasma bevel etcher of claim 12, further comprising:
a lower support having a cylindrical top portion on which the semiconductor substrate is supported;
a lower plasma exclusion zone (PEZ) ring supported on the top portion of the lower support;
a lower annular electrode surrounding the lower PEZ ring, having an upper plasma-exposed surface;
an upper dielectric component disposed above the lower support and having a cylindrical bottom portion opposing the top portion of the lower support;
an upper PEZ ring surrounding the upper dielectric component and opposing the lower PEZ ring;
the upper extension electrode surrounding the upper PEZ ring;
at least one radio frequency (RF) power source adapted to energize at least one species of process gas into a plasma during operation of the plasma bevel etcher, wherein the plasma is useful for cleaning the bevel edge of the semiconductor substrate.

14. The plasma bevel etcher of claim 13, wherein the upper PEZ ring has an outer flange partially overlapping the truncated conical surface of the upper extension electrode.

15. The plasma bevel etcher of claim 13, wherein the outer diameter of the upper and lower PEZ rings are greater than, lesser than, or equal to the diameter of the substrate.

16. A method of cleaning the bevel edge of a semiconductor substrate in the plasma bevel etcher of claim 13, comprising:
placing the semiconductor substrate on the lower support;
lowering the upper dielectric component or raising the lower support;
introducing a process gas into a reaction zone surrounding the bevel edge of the semiconductor substrate;
energizing the process gas so as to generate a plasma in the reaction zone; and
cleaning the bevel edge with the plasma.

17. A method of manufacturing the extension electrode of claim 1, comprising:
machining a truncated conical surface on a ring of aluminum or aluminum alloy;
roughening at least the truncated conical surface;
anodizing the roughened truncated conical surface;
coating the anodized truncated conical surface with a ceramic material using plasma spray deposition.

18. The method of claim 17, wherein the truncated conical surface is roughened to a roughness (Rₐ) between about 75 and 200 microinches prior to anodization.

19. The method of claim 17, wherein the truncated conical surface is anodized to a thickness of about 0.002 inch.

20. The method of claim 17, wherein the ceramic material is yttria and the plasma sprayed ceramic coating has a thickness of about 0.002 to 0.008 inch.
